(19) United States
(12) Patent Application Publication
(10) Pub. No.: US 2002/0141257 A1
(43) Pub. Date: Oct. 3, 2002

(54) Layout method for semiconductor integrated circuit

(75) Inventor: Tomoko Ide, Kanagawa (JP)

Correspondence Address: SUGHRUE MION, PLLC, 2100 PENNSYLVANIA AVENUE, N.W., WASHINGTON, DC, 20037, US

(73) Assignee: NEC CORPORATION

(21) Appl. No.: 10/103,887

(22) Filed: Mar. 25, 2002

(30) Foreign Application Priority Data
Mar. 28, 2001 (JP) 93099/2001

(51) Int. Cl. G11C 7/00

(52) U.S. Cl. 365/200

(57) ABSTRACT

The lay out method of a semiconductor integrated circuit according to the present invention which performs wiring between circuit blocks using the arrangement of a plurality of circuit blocks constituting a semiconductor integrated circuit and a wiring consisting of a plurality of wiring layers has an arrangement step for arranging circuit blocks, a wiring barrier region setting step which makes a wiring barrier region to be wiring enabled for a specific wiring layer out of a plurality of wiring layers by setting to surround at least one circuit block in a ring form out of a plurality of circuit blocks, a wiring step for generating a wiring which connects the terminal of a circuit block with the terminal of another circuit block, and an antenna ratio decision step in which whether or not the antenna ratio, defined by the quotient obtained by dividing the side-face area of a wiring for each layer connected to a terminal by the gate area of transistors constituting a circuit block connected to the terminal, is smaller than an allowable reference value, outputs the wiring as generated in the wiring step as the wiring pattern for mask manufacture when the antenna ratio is smaller than the allowable reference value, and returns to the wiring processing in the wiring step in order to reduce the antenna ratio to be smaller than the allowable reference value when the antenna ratio is larger than the allowable reference value.

### BACKGROUND OF THE INVENTION

1. Field of the Invention

The present invention relates to a layout method for a semiconductor integrated circuit, and more particularly to a layout method of a semiconductor integrated circuit which can prevent gate breakdown due to antenna effect.

1. Description of the Prior Art

Accompanying the advancement of fine processing technology in semiconductors in the recent years, high density processing and high integration processing of the semiconductor integrated circuits have seen a progress, and the manufacturing processes of the semiconductor integrated circuits are entering the deep sub-micron era. Under these circumstances, various kinds of problem with which we have never encountered in the past have become conspicuous, one of which is the problem of gate breakdown due to antenna effect.

In the etching process of the wirings, the exposed parts of a wiring conductors are the side faces of the wirings so that the area of the exposed parts of the wiring conductors is peripheral length×thickness of the wiring film. The quotient of the area of the exposed parts of the wiring conductors by the area of the gate film is defined as the antenna ratio. When the antenna ratio grows, the charge accumulated on the gate film increases relatively, charges due to the plasma flows into the gate as a charge current via wirings of respective layers connected to the gate, as shown in FIG. 7, and gate breakdown is caused when this current exceeds the threshold.

The allowable reference value of the antenna ratio for preventing the antenna effect is determined for each manufacturing process, and after layout design it has been necessary to verify whether or not there exists a wiring pattern that exceeds the allowable reference value.

A countermeasure for preventing the breakdown of the gate due to the antenna effect on the design level has been disclosed in Japanese Patent Applications Laid Open No. 2000-174131, and in the semiconductor integrated circuit according to the invention, external wiring of level block is connected to an internal wiring via a dedicated I/O cell. As a result, the internal wiring of the layer block is not connected directly to the external wiring and the charge current from the external wiring is absorbed by the dedicated I/O cell, and it is possible to prevent breakdown of the gate.

Since, however, the direct inflow of the charge current which becomes a cause of gate breakdown from the external wiring is prevented by the provision of a dedicated I/O cell in the Japanese Patent Applications Laid Open No. 2000-174131, it leads to the problems that the layout area is increased due to increase in the number of elements constituting the semiconductor integrated circuit, and that the wiring delay is increased caused by a parasitic capacitance added to the dedicated I/O cell.

### BRIEF SUMMARY OF THE INVENTION

### Object of the Invention

It is the object of the present invention to provide a layout method of a semiconductor integrated circuit which is capable of preventing breakdown of the gate of a transistor due to the charge current generated in the wiring process without increasing the number of circuit elements.

### SUMMARY OF THE INVENTION

The layout method of a semiconductor integrated circuit according to the present invention which performs wiring between circuit blocks using wirings of a plurality of circuit blocks constituting a semiconductor integrated circuit and a plurality of wiring layers, has an arrangement process of arranging circuit blocks, a wiring barrier region setting process in which a wiring barrier region, which enables wiring for a specific wiring layer from among a plurality of wiring layers, is set so as to surround at least one circuit block out of a plurality of circuit blocks, a wiring process which generates a wiring that connects the terminal of one circuit block to the terminal of another circuit block, and an antenna ratio decision process which decides whether the antenna ratio, defined by the quotient obtained by dividing the wiring side-face area for each layer connected to a terminal by the gate area of transistors connected to the terminal and constitute a circuit block, is smaller than an allowable reference area, outputs the wiring formed in the wiring process as a wiring pattern for manufacturing a mask when the antenna ratio is decided to be smaller than the allowable reference area, and goes back to the wiring processing in the wiring process to reduce the antenna ratio to be smaller than the allowable reference area when the antenna ratio is decided to be larger than the allowable reference area.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a schematic layout diagram for describing the design method of a semiconductor integrated circuit according to the present invention;

FIG. 2A is an enlarged view of the broken line portion 132 of a circuit block 13 and a wiring barrier region 131 shown in FIG. 1, FIG. 2B is a plan view of a wiring pattern which connects a circuit block terminal 22 and an external wiring 246 for the case of n=1 and m=5, and FIG. 2C is a sectional view of schematic structure of the wiring structure shown by the plan view of FIG. 2B;

FIG. 3 is a schematic layout diagram for describing specifically the design method of the semiconductor integrated circuit according to the invention;

FIG. 4 is a flow chart for describing the design method of the semiconductor integrated circuit according to the invention;

FIGS. 5A and 5B are schematic layout diagrams for describing an embodiment of design method of the semiconductor integrated circuit according to the invention;

FIG. 6A is a schematic layout diagram for describing another embodiment of the design method of the semiconductor integrated circuit according to the invention and FIG. 6B is a schematic layout diagram for describing problems when the design method shown in FIG. 6A is not used; and

FIG. 7 is a sectional view of a schematic structure for describing problems according to the conventional design method of the semiconductor integrated circuit.

### DETAILED DESCRIPTION OF THE INVENTION

Next, referring to the drawings, the embodiments of the present invention will be described.

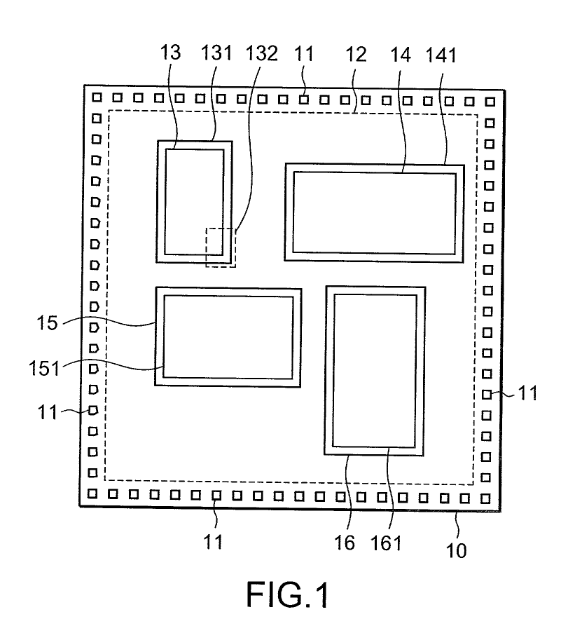

In FIG. 1 for schematically describing the design method of a semiconductor integrated circuit according to the present invention, 10 is a semiconductor chip, 11 is a bonding pad, 12 is an internal region for arranging circuit blocks, 13 to 16 are circuit blocks such as CPU, RAM, ROM and ALU, and 131 to 161 are wiring barrier regions arranged in a ring form adjacent to the outer frame of respective circuit blocks 13 to 16.

If wirings among circuit blocks 13 to 16 and between the circuit blocks 13 to 16 and input/output buffers (not shown) arranged on the outside of the internal region 12 without providing wiring barrier regions 131 to 161, then wirings having a large wiring length among these wirings are affected extremely by the antenna effect in which charge currents flow into the circuit blocks 13 to 16 through these wirings with large wiring length, breaking the gates of the transistors constituting the circuit blocks 13 to 16.

Because of this, in this invention, ring-form wiring barrier regions 131 to 161 are provided along the outer periphery of the circuit blocks 13 to 16, to reduce the antenna ratio and prevent breakdown of the gates by arranging to have automatic wiring so as to shorten the length of the wirings that may be affected by the antenna effect, among the wirings that are connected from the outside to the circuit blocks 13 to 16.

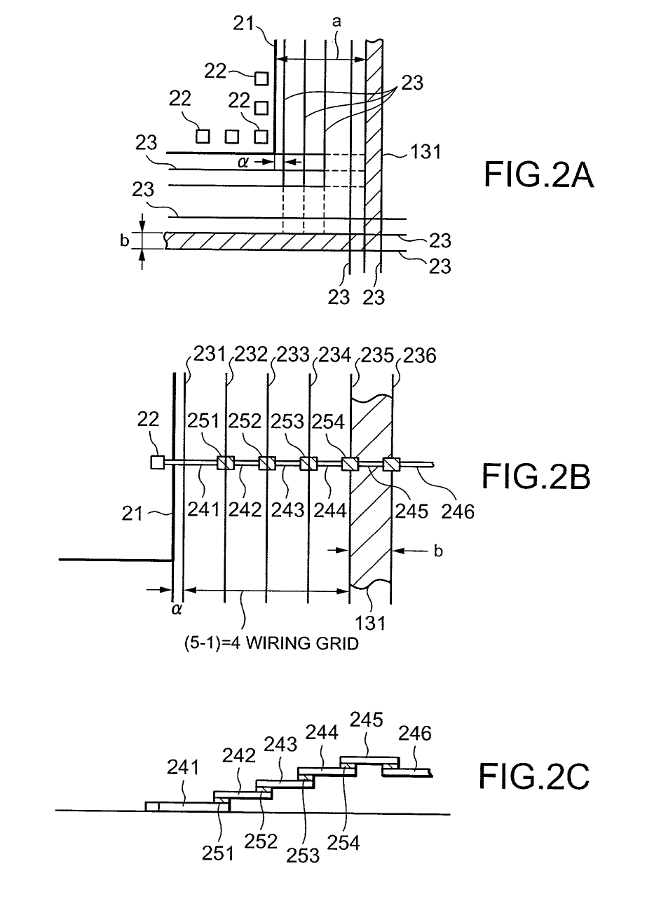

In FIG. 2A which shows an enlarged view of the portion 132 indicated by the broken lines of the circuit block 13 and the wiring barrier region 131 in FIG. 1, there are shown a circuit block outer frame 21 representing the outer shape of the circuit block 13, circuit block terminals 22 consisting of input terminals or output terminals or input/output terminals, wiring grids 23 for performing automatic wiring and the wiring barrier region 131.

The wiring barrier region 131 is set as wiring grids or only the uppermost wiring layer, and hence in the automatic wiring process which performs wiring processing to the interior of the circuit blocks 13 to 16 from the outside of the circuit blocks 13 to 16 via the wiring barrier region 131, the internal wirings of the wiring barrier region 131 and the external wirings are connected in the wiring barrier region 131 automatically in the uppermost wiring.

Here, the width b of the wiring barrier region 131 is sufficient if is given one wiring grid portion necessary for arranging two vias for connecting the wiring from the uppermost wiring to the wiring layer one layer below.

Moreover, the interval a varies depending upon the manufacturing process, the number of wiring layers to be used, and the like, it is calculated by Eq. (1) below:

a=(m−n)+α. (1)

In Eq. (1), n (a natural number) is the wiring level of the circuit block terminals 22, and m (a natural number which usually satisfies m>n) is the wiring level of the uppermost wiring of the semiconductor integrated circuit as a whole. Moreover, α is the interval between a wiring grid and a circuit block arrangement grid when the circuit block 13 to 16 are arranged on circuit block arrangement grids that are not on the wiring grids.

Describing Eq. (1) more specifically by reference to FIG. 2B and FIG. 2C, FIG. 2B shows a plan view for connecting the circuit block terminal 22 and an external wiring 246 for the case of n=1 and m=5. Reference numerals 231 to 236 are wiring grids, 241 to 245 are wirings of first to fifth layer, 246 is the wiring of the fourth layer, 251 is a via for connecting the first layer wiring 241 and the second layer wiring 242, 252 is a via for connecting the second layer wiring 242 and the third layer wiring 243, and similarly for 253 and 254.

As is clear from the figure, the interval between the wiring grid 231 and the wiring grid 235 is 5 −1=4 (wiring grids)

Accordingly, the interval between the outer frame 21 of the circuit block and the wiring barrier region 131 can be evaluated as the sum of the four wiring grids in the above and the interval α between the circuit block arrangement grid and the wiring grid.

As described in the above, wiring grids 23 are provided between the wiring block outer frame 21 and the wiring barrier region 131, wirings to be connected from the outside of the circuit blocks 13 to 16 are connected to the wirings of the uppermost wiring layer of the semiconductor integrated circuit in the wiring barrier region 131, and inside the wiring barrier region 131 and are eventually connected to the circuit block terminal 22 via the wirings on the wiring grids 23.

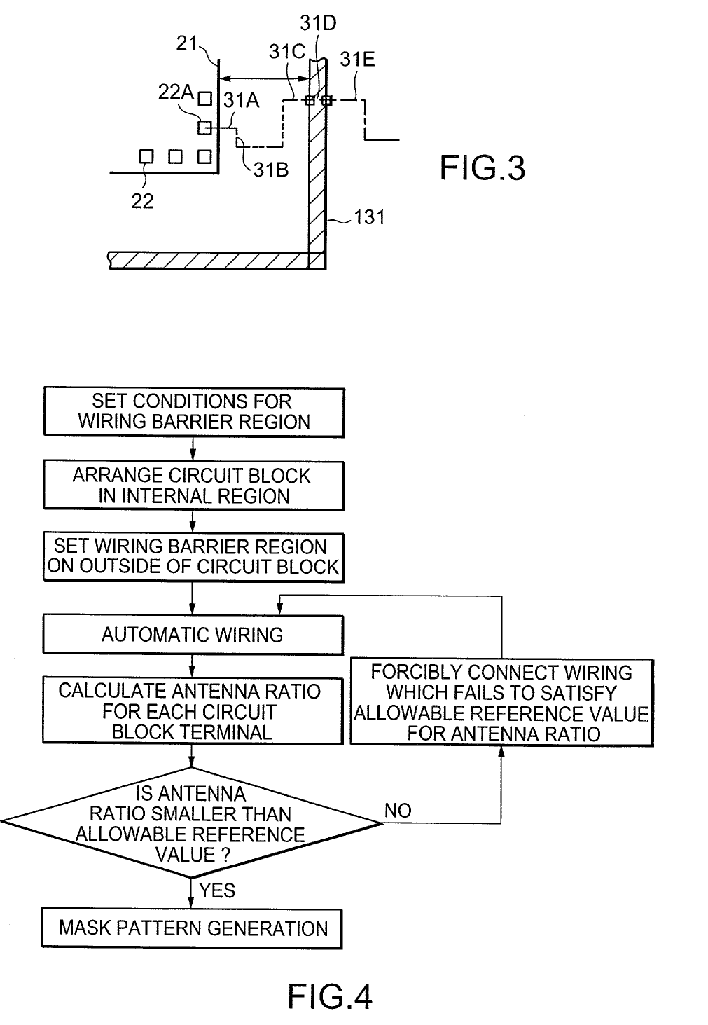

Next, referring to FIG. 3, the semiconductor integrated circuit according to the present invention will be described specifically.

FIG. 3 describes a wiring pattern of connection between the circuit block terminal 22A when the circuit barrier region 131 shown in FIG. 2 is set and an external wiring 31E of the circuit block.

A wiring 31A on the same wiring layer as the circuit block terminal 22A is led out from the circuit block terminal 22A, and is connected to a wiring 31B on the layer one level higher than that of the wiring 31A. The wiring layer is changed successively in this manner until it is connected to a wiring 31C on the (m−1)-th layer.

Then, the wiring 31C is connected to the m-th layer wiring 31D through the via arranged on the left end of the wiring barrier region 131. Similarly, the wiring 31D is connected to the (m−1)-th layer wiring 31E through a via arranged on the right end of the wiring barrier region 131. In this way, the external wiring 31E and the circuit block terminal 22A are connected through the wiring 31D of the upper most layer on the wiring barrier region 131.

As can be seen from the description in the above, by focusing the attention to the wirings connected to the circuit block terminal 22A, these wirings can be classified into the wirings 31A to 31C on the inside of the circuit wiring barrier region 131, the wiring 31D on the wiring barrier region 131 and the wiring 31E on the outside of the wiring barrier region 131.

The wirings from the first layer to the uppermost m-th layer are formed sequentially by plasma etching, and the wirings 31A to 31C on the inside of the wiring barrier region 131 are connected to the wiring 31E on the outside of the wiring barrier region 131 in the formation process of the uppermost wiring. In the plasma etching process up to the (m−1)-th layer, the wirings that are connected to the circuit block terminal 22A are only the wirings 31A to 31C on the inside of the wiring barrier region 131. Since these wirings 31A to 31C are connected on the inside of the wiring barrier region 131 arranged near the circuit block outer frame 22, their wiring length will not get large. Accordingly, in the plasma etching process up to the (m−1)-th layer wiring the antenna ratio stays small and the gates of the transistors will not be damaged.

As to the plasma etching process of the m-th layer, wiring which becomes the object of the plasma etching is only the wiring on the uppermost m-th layer, and the wirings on the layers bellow this have already gone through the plasma etching, wiring that is affected by the antenna ratio is only that on the uppermost layer.

Accordingly, the wiring length of the wiring 31D on the uppermost layer that connects the two vias arranged on both sides of the wiring barrier region 131 is a sufficiently small length of about one wiring grid, so that the antenna ratio of the wiring connected to the circuit block terminal 22A is sufficiently small. As a result, it is possible to prevent the breakdown of the gates of the transistors connected to the circuit block terminal 22A.

Next, referring to the flow chart shown in FIG. 4, the design method of the semiconductor integrated circuit according to this invention will be described.

First, conditions on the interval between the outer frame of the circuit block and the wiring barrier region, the width of the wiring barrier region the shape of the wiring barrier region, the allowable reference value, or the like are set in step S1.

Next, the circuit blocks constituting the semiconductor integrated circuit is arranged in the internal region shown in FIG. 1 in step S2, and ring-form wiring barrier regions shown in FIGS. 1 and 2 are set on the outside of the circuit blocks in step S3.

Following that, an automatic wiring processing which automatically carries out wirings between the circuit blocks and the wirings between the circuit blocks and the input/output buffers arranged on the outside of the internal region in step S4, and the antenna ratio is calculated by referring to the wiring layer, wiring length, wiring width or the like of the wirings connected to each of the circuit block terminal in step S5.

Next, it is decided whether the antenna ratio calculated in step S5 is smaller than the allowable reference value in step S4 is decided in step S6, and when it is decided that the antenna ratio is smaller than the allowable reference value, the wirings generated in step S4 is chosen as the final wiring pattern,. and a mask pattern for generation of a mask is prepared using the final wiring pattern in step S7.

When the antenna ratio exceeds The allowable reference value, wiring paths that are exceeding the allowable reference value are searched, the wirings on the wiring paths are forcibly adjusted so as to satisfy the allowable reference value, and the automatic wiring processing is carried out for the remaining wirings.

In the above description, it has been assumed in that the wiring barrier region 131 is set only on the wiring grid of the uppermost wiring layer, so that the internal wiring and the external wiring of the wiring barrier region 131 are connected automatically on the uppermost wiring layer. However, similar effect can be obtained even by setting the layer up to one layer below the uppermost wiring layer relative to the wiring barrier region to be forbidden for wiring.

In other words, since the wiring barrier region is set to be forbidden region to the first layer wiring through the (m−1)-th layer wiring, no automatic wiring will take place in this wiring barrier region, and only the m-th layer being the uppermost wiring layer is the objective wiring of automatic wiring.

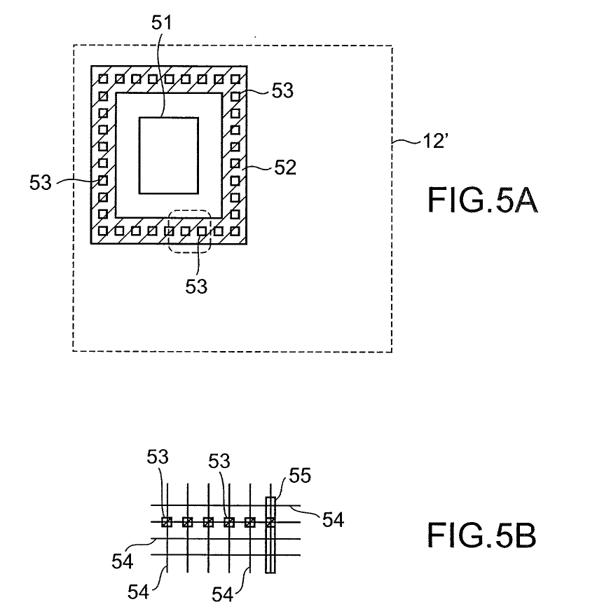

Next, referring to FIG. 5A and FIG. 5B, a second embodiment of the semiconductor integrated circuit according to the invention will be described.

In FIG. 5A, reference numeral 51 is a circuit block arranged in an internal region 12′, and a wiring barrier region 52 is set along the outer periphery of the circuit block 51. In the wiring barrier region 52, ring-form vias 53 are formed on the wiring grid. Namely, these vias 53 are defined so as to connect, respectively, the first layer wiring to the second layer wiring, the second layer wiring to the third layer wiring, and so on up to the (m−2)-th layer wiring to the (m−1)-th wiring.

As shown in FIG. 5B, these vias are arranged linearly along one side of the wiring barrier region 52 with a minimum wiring grid unit relative to each wiring grid 54, the first layer wiring to the (m−1) -th layer wiring cannot provide wiring on the wiring barrier region 52. On the other hand, the m-th layer wiring 55 shown in FIG. 5B is capable of providing wirings on the wiring grids 54.

Moreover, since the wiring barrier region 52 and the vias 53 constituting the wiring barrier region 52 become unnecessary data when it is decoded in step S6 in FIG. 4 14 that the antenna ratio is smaller than the allowable reference value, they are deleted from the design data prior to the mask pattern generation in step S7.

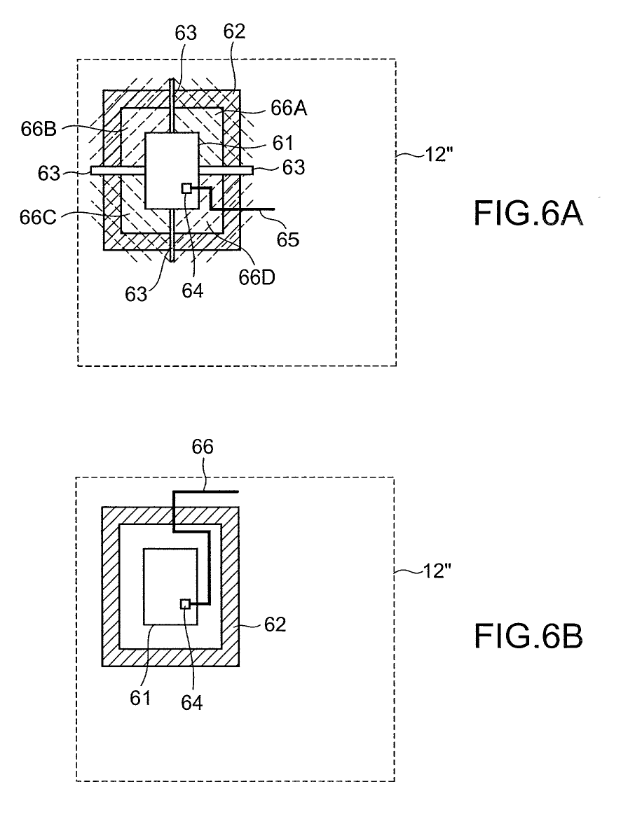

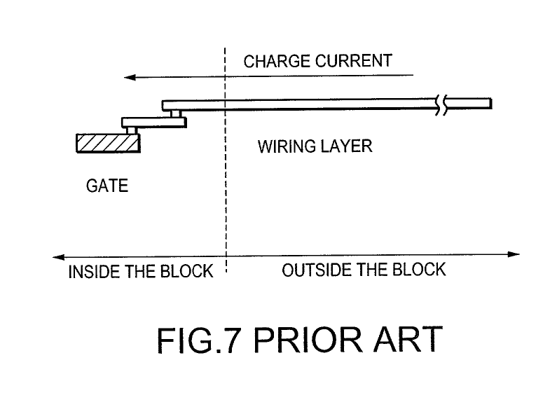

Next, referring to FIG. 6A and FIG. 6B, a third embodiment of the semiconductor integrated circuit according to the invention will be described.

In FIG. 6A, reference numeral 61 is a circuit block in an internal region 12″, and a wiring barrier region 62 is provided on the outside of the circuit block 61. Moreover, a wiring barrier region division pattern 63 which divides the region between the outer frame of the circuit block 61 and the outer frame of a wiring barrier region 65 into a plurality of regions is provided.

In the wiring barrier region division pattern 63, it is set such that wirings of all layers, namely from the first layer to the m-th layer are inhibited. In the example shown in FIG. 6A, the region between the outer frame of the circuit block 61 and the outer frame of the wiring barrier region 65 is divided into four regions 66A to 66D.

Accordingly, the wiring 65 which is connected from a circuit block terminal 64 constituting the circuit block 61 to the outside of the circuit block 61 undergoes a wiring processing within the division region 66D, and the wiring will not creep into another division region, for example, division region 66A.

As a result, there will occur no such a case as shown in FIG. 6B in which wiring to the outside of the circuit block 61 is realized by going around the region between the outer frame of the circuit block 61 and the outer frame of the wiring barrier region 65. Accordingly, as can be seen readily from FIG. 6A and FIG. 6B, the semiconductor integrated circuit according to this invention there will arise no deterioration in the operating speed due to redundancy of the wiring length and increase in the wiring capacity, nor such a problem as an increase in the antenna ratio due to increase in the wiring length.

In other words, the semiconductor integrated circuit according to this embodiment, a wiring which is connected from the circuit block terminal to the outside of the circuit block, in the region between the outer frame of the circuit block and the outer frame of the wiring barrier region, can go through automatic wiring with short wiring length without having a redundant length, so that the antenna ratio can be reduced and the wiring capacity can be made small and the semiconductor integrated circuit can be operated at high speed.

In FIG. 6A, the case is described in which the region between the outer frame of the circuit block and the outer frame of the wiring barrier region is divided into four regions, but a division method in which the region is divided into eight regions or 16 regions may also be employed.

In short, what is important is that by dividing the region between the outer frame of the circuit block and the outer frame of the wiring barrier region into a plurality of regions, make a wiring which is connected from the circuit block terminal to the outside of the circuit block to be connected to an external wiring by way of one divided region so that the wiring length will not be increased in the divided region.

Moreover, in the above, description has been given assuming that wiring in the wiring barrier region is possible only on the uppermost wiring layer. However, it is not necessarily be the uppermost wiring layer, and it may be set that wiring is allowed to a specific wiring layer out of all wiring layers

Furthermore, it is not necessary to set the wiring barrier region in a ring form for all circuit blocks. For example, when it is clear that an external wiring with large wiring length will not come in to be connected to the interior of the circuit block 14 from the right-hand side of the wiring barrier region 141 in FIG. 1, the right side of the wiring barrier region 141 maybe deleted to give it the shape of an open box. By so doing, it is possible to reduce the area of the wiring barrier region.

As described in the above, the layout method of the semiconductor integrated circuit according to the present invention can prevent the gate breakage due to the antenna effect for gates constituted by general purpose circuit blocks such as CPU, memory, flip-flop circuit, or the like without the need for special elements as is the case in the conventional technique. Since no special design is needed for circuit blocks, funds for design of library data and the like concerning the circuit blocks may be diverted for some other more useful purposes.

Moreover, since special elements are not needed, it is possible to reduce the chip area, and since the net list data of semiconductor integrated circuits can be reduced, it is possible to enhance the design efficiency.

Furthermore, in the design method of the semiconductor integrated circuit according to the present invention, breakdown of the gates due to the antenna effect is prevented by providing a ring-form wiring barrier region to adjacent circuit blocks. Therefore, among the wirings of various wiring layers connected to the circuit block terminals, those large wiring length that are responsible to the antenna effect are made to be wirings outside of the wiring barrier region. As a result, even when there are found wirings whose antenna ratio is larger than the allowable reference value in step S6 of FIG. 4, correction of the wiring need only be carried out aimed at wirings outside of the wiring barrier region, and it is not necessary to change the wiring patterns in the circuit blocks or inside the wiring barrier region. Accordingly, the correction can be done easily.

Although the invention has been described with reference to specific embodiments, this description is not meant to be construed to a limited sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A layout method of a semiconductor integrated circuit executing wiring between circuit blocks by using arrangement of a plurality of circuit blocks constituting the semiconductor integrated circuit and a wiring consisting of a plurality of wiring layers, comprising:
an arrangement step for arranging said circuit blocks,
a wiring barrier region setting step for setting a wiring barrier region which enables wiring for a specific wiring layer out of said plurality of wiring layers to be wired there on by surrounding at least one of the plurality of circuit blocks out of said plurality of circuit blocks,
a wiring step for generating a wiring which connects the terminal of said circuit block and the terminal of another circuit block, and
an antenna ratio decision step which decides whether or not the antenna ratio, as defined by the quotient of division of the side-face area of the wiring oh each layer connected to said terminal by the area of the gate of transistors constituting said circuit block connected to said terminal, is smaller than an allowable reference value, and outputs the wiring generated in said wiring step as the wiring pattern for mask manufacture when said antenna ratio is decided to be smaller than the allowable reference value, and returns to said wiring step in order to reduce said antenna ratio to be smaller than the allowable reference value when said antenna ratio is decided to be larger than the allowable reference ratio.

2. The layout method of a semiconductor integrated circuit as claimed in claim 1, wherein the specific wiring layer is chosen to be the uppermost wiring layer among said plurality of wiring layers.

3. The layout method of a semiconductor integrated circuit as claimed in claim 1, wherein a wiring grid of said specific wiring layer is set among respective wiring grids, with respect to said wiring barrier region.

4. The layout method of a semiconductor integrated circuit as claimed in claim 1, wherein a wiring inhibition region except for said wiring inhibition region of said specific wiring layer, among the wiring inhibition region of respective layers, with respect to said wiring barrier region.

5. The layout method of a semiconductor integrated circuit as claimed in claim 1, wherein vias are set for respective layers except for said via of said specific wiring layer among vias of respective layers, with respect to said wiring barrier region.

6. A layout method of a semiconductor integrated circuit for performing wiring between wiring blocks using arrangement of a plurality of circuit blocks constituting a semiconductor integrated circuit and a wiring consisting of a plurality of wiring layers, comprising:
an arrangement step for arranging said circuit blocks, a wiring barrier region setting step for setting a wiring barrier region which enables wiring for a specific wiring layer out of said plurality of wiring layers by setting at least one of said circuit block in ring form out of said plurality of circuit blocks.
a step of forming a wiring barrier region division pattern at boundaries of divided regions to prevent wiring beyond said divided regions by dividing the space between the outside of circuit block and said wiring barrier region into a plurality of divided regions,
a wiring step for generating a wiring which connects the terminal of said circuit block and the terminal of another of said circuit block, and
an antenna ratio decision step in which whether or not the antenna ratio, defined by the quotient obtained by dividing the side-face area of wiring of each layer connected to said terminal by the gate area of transistors constituting said circuit block connected to said terminal, is smaller than an allowable reference value, outputs the wiring generated in said wiring step as a wiring pattern for mask manufacture when the antenna ratio is smaller than the allowable reference value, and returns to the wiring processing in said wiring step in order to reduce the antenna ratio to be smaller than the allowable reference value when the antenna ratio is larger than the allowable reference value.
